(19) United States
(12) Patent Application Publication
(10) Pub. No.: US 2010/0233864 A1
(43) Pub. Date: Sep. 16, 2010

(54) Methods of fabricating a semiconductor device

(75) Inventors: Ho Lee, Gheonan-si (KR); Moon-han Park, Gyeonggi-do (KR); Hwa-sung Rhee, Seongnam-si (KR); Myung-sun Kim, Hwaseong si (KR); Hoi-sung Chung, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/656,842

(22) Filed: Feb. 17, 2010

(30) Foreign Application Priority Data
Mar. 13, 2009 (KR) 10-2009-0021864

(51) Int. Cl. H01L 21/336

(52) U.S. Cl. 438/306; 257/E21.409

(57) ABSTRACT

Methods of fabricating a semiconductor device are provided, the methods include forming a gate stack on a substrate, forming an insulation layer on the substrate to cover the gate stack, forming a spacer at both side walls of the gate stack by etching the insulation layer, and ion implanting impurities in the spacer or the insulation layer.

### CROSS-REFERENCE TO RELATED APPLICATIONS

This application claims the benefit of priority under 35 U.S.C. §119 from Korean Patent Application No. 10-2009-0021864, filed on Mar. 13, 2009, in the Korean Intellectual Property Office, the disclosure of which is incorporated herein in its entirety by reference.

### BACKGROUND

1. Field

Example embodiments relate to methods of fabricating a semiconductor device. Other example embodiments relate to methods of fabricating a semiconductor device which reduces parasitic capacitance by implanting ions in a spacer and/or an etch stop layer.

2. Description of the Related Art

As the semiconductor devices become more highly-integrated and/or have larger capacity, the size of a unit cell and the distance between cells decreases. Accordingly, the distance between gates and/or the distance between a gate and a contact gradually decreases. A decrease in the size and/or distance may cause some problems such as an increase of an undesired parasitic capacitance.

As the size of a cell decreases, the thickness of an insulator functioning as a dielectric of a capacitor also decreases. The parasitic capacitance increases as the thickness of the insulator decreases. The increased parasitic capacitance may account for over 30% of the total gate capacitance. As such, an increase in the parasitic capacitance may have a substantial influence on the performance of an overall circuit. For example, the increased parasitic capacitance may cause an alternate current (AC) delay.

### SUMMARY

Example embodiments relate to methods of fabricating a semiconductor device. Other example embodiments relate to methods of fabricating a semiconductor device which reduces parasitic capacitance by implanting ions in a spacer and/or an etch stop layer.

Example embodiments provide a method of fabricating a semiconductor device that may increase performance of a circuit by decreasing parasitic capacitance.

According to example embodiments, there is provided a method of fabricating a semiconductor device, which includes forming a gate stack on a substrate, forming an insulation layer on the substrate to cover the gate stack, forming a spacer at both side walls of the gate stack by etching the insulation layer, and ion implanting impurities in the spacer to reduce a dielectric constant of the spacer.

The insulation layer may include a nitride. The impurities include at least one of carbon and fluorine. The impurities may be either monomers or clusters.

The ion implanting of the impurities may include forming a mask layer to expose an ion implantation area on the substrate. In the ion implanting of the impurities, a dose of the impurities may be selected such that the concentration of the impurities in the spacer is between about 10²¹ atoms/cm³ to about 10²² atoms/cm³.

The method may include forming a source/drain region in the substrate at both sides of the gate stack by ion implantation, forming an etch stopping nitride layer on the substrate, secondly ion implanting the impurities in the etch stopping nitride layer, forming an interlayer insulation layer on the etch stopping nitride layer, forming a contact hole through the interlayer insulation layer and the etch stopping nitride layer to expose the source/drain region, and forming a contact plug on the source/drain region.

According to other example embodiments, there is provided a method of fabricating a semiconductor device, which includes forming a gate stack on a substrate, forming an insulation layer on the substrate to cover the gate stack, ion implanting impurities in the insulation layer, and forming a spacer at both side walls of the gate stack by etching the insulation layer.

In the ion implanting of the impurities, ion implantation energy may be selected such that a projection range is smaller than a thickness of the insulation layer.

The method may include annealing the substrate to densify the insulation layer, prior to the etching of the insulation layer.

According to example embodiments, there is provided a method of fabricating a semiconductor device, which includes forming a gate stack on a substrate, forming a spacer at both side walls of the gate stack, forming a source/drain region in the substrate at both sides of the gate stack by ion implantation, forming an etch stopping layer on the gate stack to cover the gate stack, ion implanting impurities in the etch stopping layer, forming an interlayer insulation layer on the etch stopping layer, forming a contact hole through the interlayer insulation layer and the etch stopping layer to expose the source/drain region, and forming a contact plug on the source/drain region.

### BRIEF DESCRIPTION OF THE DRAWINGS

Example embodiments will be more clearly understood from the following detailed description taken in conjunction with the accompanying drawings. FIGS. 1-8 represent non-limiting, example embodiments as described herein.

FIG. 1 is a flowchart for explaining a method of fabricating a semiconductor device according to example embodiments;

FIGS. 2A-2E are cross-sectional views for showing the process sequence of a method of fabricating a semiconductor device according to example embodiments;

FIG. 3 is a flowchart for explaining a method of fabricating a semiconductor device according to example embodiments;

FIGS. 4A-4C are cross-sectional views for showing the process sequence of a method of fabricating a semiconductor device according to example embodiments;

FIG. 5 is a flowchart for explaining a method of fabricating a semiconductor device according to example embodiments;

FIGS. 6A-6E are cross-sectional views for showing the process sequence of a method of fabricating a semiconductor device according to example embodiments;

FIG. 7 is a graph for explaining a degree of a decrease in the parasitic capacitance of a semiconductor device fabricated according to the method of FIG. 1; and

FIG. 8 is a graph for explaining a degree of a decrease in the parasitic capacitance of a semiconductor device fabricated according to the method of FIG. 5.

### DETAILED DESCRIPTION OF EXAMPLE EMBODIMENTS

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present invention is not limited to example embodiments described.

Example embodiments relate to methods of fabricating a semiconductor device. Other example embodiments relate to methods of fabricating a semiconductor device which reduces parasitic capacitance by implanting ions in a spacer and/or an etch stop layer.

In the example embodiments, a gate stack functions as a type of a capacitor. If a constant voltage is applied to a gate electrode layer of the gate stack, a channel connecting a source region with a drain region is formed under a gate insulation layer of the gate stack. An intrinsic capacitance of the gate stack may be determined based on the relationship between the voltage applied to the gate electrode layer and carriers gathered to form the channel. The intrinsic capacitance of the gate stack may be maintained at a constant level during (or for) the operation of a semiconductor device.

In addition to the intrinsic capacitance of the gate stack, the gate stack may have parasitic capacitance. The parasitic capacitance may include the capacitance of a capacitor formed between the gate electrode layer and the source/drain region including a lightly-doped source drain region. The parasitic capacitance may include the capacitance of a capacitor formed between a contact plug and the gate electrode. The parasitic capacitance may cause an alternate current (AC) delay and/or may have an influence on the operational characteristics of a semiconductor device.

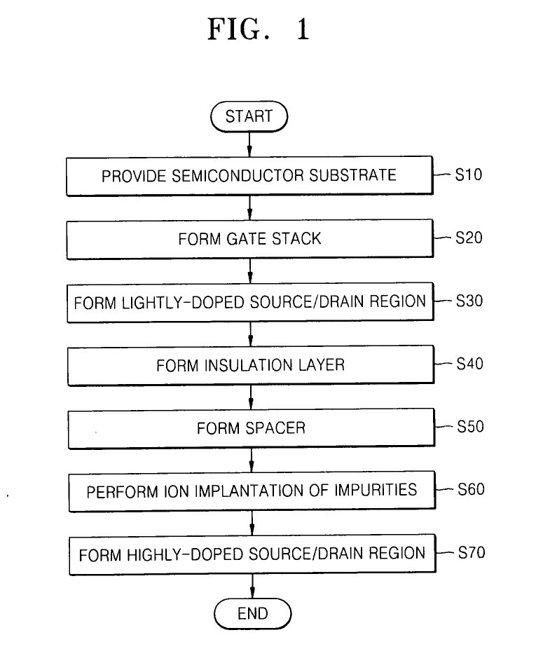

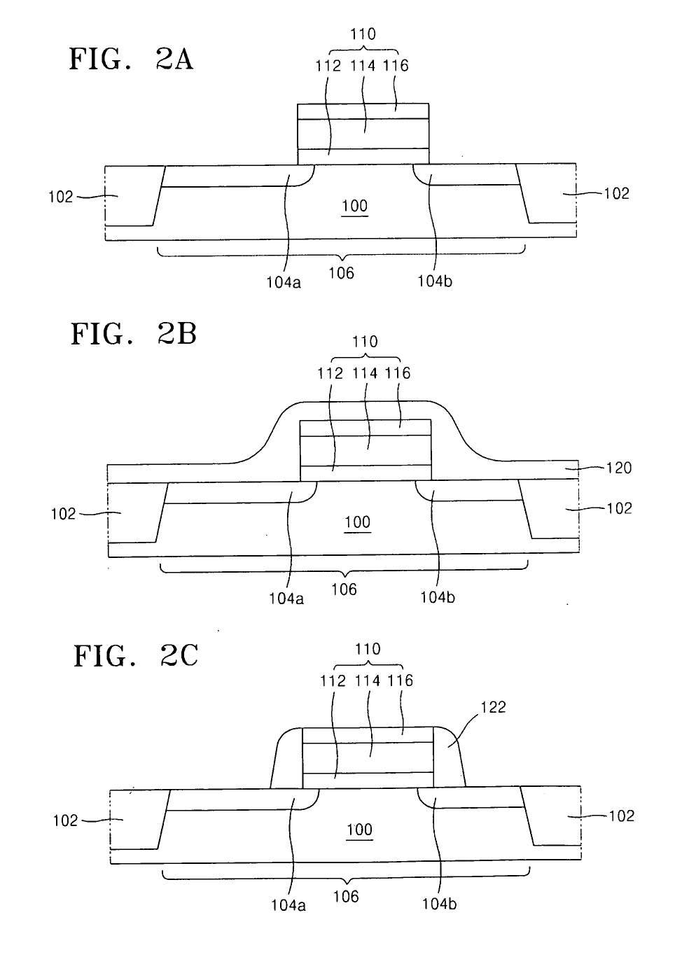

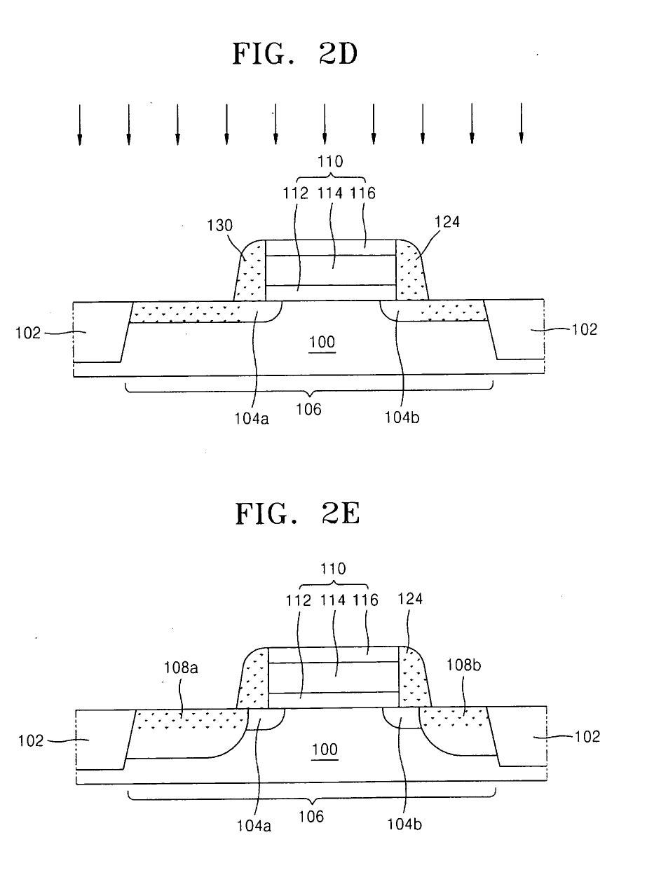

FIG. 1 is a flowchart for explaining a method of fabricating a semiconductor device according to example embodiments. FIGS. 2A-2E are cross-sectional views for showing the process sequence of a method of fabricating a semiconductor device according to example embodiments.

Referring to FIGS. 1 and 2A, a semiconductor substrate 100 including an active region 106 in which a field-effect transistor is to be formed is provided (S10). The semiconductor substrate 100, which is a substrate used for a manufacturing process of a semiconductor device, may include a semiconductor material (e.g., silicon or silicon-germanium). The semiconductor substrate 100 may include an epitaxial layer, a silicon-on-insulator (SOI) layer, a semiconductor-on-insulator (SEOI) layer and/or silicon-on-sapphire (SOS) layer.

The active region 106 may be defined by a device isolation layer 102. The device isolation layer 102 may be a local oxidation of silicon (LOCOS) type or a shallow trench isolation (STI) type. An n-type field-effect transistor (FET) (not shown) or a p-type FET (not shown) may be formed on the active region 106. The active region 106 may include an n-well or a p-well according to the type of a semiconductor device to be formed in the active region 106.

A stack gate 110 is formed on the active region 106 (S20). The gate stack 110 may be formed by sequentially forming a gate insulation layer 112, a gate electrode layer 114, and a capping layer 116 on and above the active region 106, and patterning the layers. The capping layer 116 may protect the gate insulation layer 112 and the gate electrode layer 114.

The gate insulation layer 112 may be a silicon oxide layer. The gate insulation layer 112 may include a high dielectric material having a dielectric constant higher than a silicon oxide (e.g., metal oxides including Al₂O₃, ZrO₂, HfO₂, TiO₂, Y₂O₃ and La₂O₃ and combinations thereof), ferroelectric materials including lead zirconate titanate (PZT) and barium strontium titanate (BST), amorphous metal silicates including HfSiₓO_{y} and ZrSiₓO_{y}, amorphous silicate oxides including HfO₂ and ZrO₂, and paraelectrics including BaₓRe₁₋ₓTiO₃ and PbZrₓTi₁₋ₓO₃. However, these are examples, and therefore not limited thereto.

The gate electrode layer 114 may be formed on the gate insulation layer 112. The gate electrode layer 114 may include a material such as highly-concentration doped polysilicon, undoped polysilicon, silicon carbide or silicon-germanium compositions. However, example embodiments are not limited thereto. Example embodiments may include the gate electrode layer 114 that includes a metal (e.g., tungsten (W), nickel (Ni), molybdenum (Mo), and cobalt (Co), metal alloys, metal oxides, mono-crystal silicon, amorphous silicon and/or silicides. Example embodiments are not limited thereto. Thus, other materials that are well-known may be used to form the gate electrode layer 114.

The capping layer 116 may be formed on the gate electrode layer 114. For example, the capping layer 116 may be a silicon nitride or a silicon oxide.

The gate insulation layer 112, the gate electrode layer 114, and the capping layer 116 may be formed in a variety of methods. For example, thermal oxidation, rapid thermal oxidation (RTO), chemical vapour deposition (CVD), plasma enhanced CVD (PECVD), high-density plasma CVD (HDP-CVD), sputtering or atomic layer deposition (ALD) may be used, as appropriate, for forming the gate insulation layer 112, the gate electrode layer 114 and the capping layer 116.

The gate stack 110 may be formed as illustrated in FIG. 2A by pattering a part of the gate insulation layer 112, the gate electrode layer 114 and the capping layer 116. An etching method to form the gate stack 110 may be, for example, anisotropic etching or inclined etching (e.g, a reactive ion etching (RIE) or plasma etching, which use a patterned hard mask layer (not shown) as an etch barrier). However, these are examples, and therefore not limited thereto.

Although the gate stack 110 is illustrated as a gate stack of a general FET including the gate insulation layer 112, the gate electrode layer 114 and the capping layer 116, example embodiments are not limited thereto. For example, the gate stack 110 may be a gate stack of a non-volatile memory having a tunnelling insulation layer, a charge storage layer, a blocking insulation layer and a gate electrode.

To prevent a hot carrier effect, which is generated in a semiconductor device to be formed in the active region 106 (e.g., a drain region of a transistor), shallow source/drain-extension regions 104a and 104b (that are hereinafter interchangeable referred to as “lightly-doped drain/source (LDD/LDS) regions”) may be formed in a part of the active region 106 of the semiconductor substrate 110 (S30). The lightly-doped drain/source regions 104a and 104b may be formed by shallow ion implantation processes using the gate stack 110 as an ion implantation mask layer.

If a semiconductor device to be formed in the active region 106 is an NMOS transistor, n-type impurities (e.g., arsenic (As)) may be implanted. Halo ions may be selectively implanted in the active region 106. The halo ions are implanted to increase the concentration of the active region 106 of the semiconductor substrate 100 after the gate stack 110 is formed, preventing (or reducing the likelihood of) a punch-through phenomenon generated as the length of a channel region is shortened (or decreases). The halo ions of a type opposite to the type of the ions implanted to form the LDD/LDS regions 104a and 104b are used. For example, p-type impurities (e.g., boron (B)) may be implanted in the active region 106.

If the semiconductor device to be formed in the active region 106 is a PMOS transistor, the p-type impurities (e.g., boron (B)) may be implanted in the active region 106. The halo ions, such as an n-type impurity (e.g., arsenic (As)), may be selectively implanted in the active region 106.

A high temperature annealing process may be performed to correct radiation damage of a substrate due to the ion implantation and guide the LDD/LDS regions 104a and 104b downwardly under the gate stack 110 as illustrated in FIG. 2A. However, in example embodiments, the LDD/LDS regions 104a and 104b may be omitted.

Referring to FIGS. 1 and 2B, an insulation layer 120 may be formed on the substrate 100, on which the gate stack 110 is formed (S40). The insulation layer 120 may include at least one of a nitride, an oxide and an oxy-nitride (e.g., a silicon nitride, a silicon oxide or a silicon oxy-nitride). The insulation layer 120 may have a structure in which a nitride layer and an oxide layer are deposited. A shallow oxide layer (not shown) may be formed on the semiconductor substrate 100 on which the gate stack 110 is formed. A nitride layer (not shown) may be formed on the oxide layer (not shown). The oxide layer may function as a buffer between the gate stack 110 and the nitride layer to remove damage on a side wall of the gate stack 110 that may be generated if the gate stack 110 is patterned. The oxide layer may function as a buffer between the gate stack 110 and the nitride layer to prevent diffusion of the impurities in the gate stack 110 to the outside. The insulation layer 120 may be formed by a variety of methods (e.g., CVD, LPCVD, PECVD, HDP-CVD, sputtering or ALD).

Referring to FIGS. 1 and 2C, a spacer 122 may be formed on both side walls of the gate stack 110 by etching the insulation layer 120 (S50). The insulation layer 120 is etched and removed not only from an upper surface of the gate stack 110 but also from most of an upper surface of the semiconductor substrate 100, except for both side walls of the gate stack 110. The anisotropic etching may be used to form the spacer 122 by leaving the insulation layer 120 on both side walls of the gate stack 110. For example, overall surface etching process (e.g., etch back using plasma) may be used to form the spacer 122. As described above, the spacer 122 may be an oxide layer and/or a nitride layer, or include a multi-layer structure where the oxide layer and the nitride layer are sequentially deposited.

Referring to FIGS. 1 and 2D, impurities 130 may be ion-implanted in the semiconductor substrate 100 in which the gate stack 110 and the spacer 122 are formed (S60). A spacer 124 including the impurities 130 and having a decreased dielectric constant may be formed. In example embodiments, the impurities 130 may be ion-implanted using an ion implantation apparatus. For example, a plasma immersion ion implantation (PIII) or plasma ion implantation (PII) may be used.

In the ion implantation method, impurities to be implanted are ionized and then accelerated so that impurity atoms having a substantially high kinetic energy are forcibly implanted in a surface of an object. The implanted impurity ions are generated by an ion source. An ion beam is accelerated by a preset (or set) operational electric potential. The ion beam is focused and scanned onto the surface of the object. The depth of implantation of the impurity atoms may be adjusted by controlling the operational electric potential. The amount of implanted impurity ions may be adjusted for accuracy.

By using the ion implantation method according to example embodiments, the concentration of impurities may be accurately adjusted, for example, within about 2%. The impurities may be uniformly implanted. According to other methods, the impurities may have a constant flow due to a process temperature, a process pressure or an electromagnetic field so that the impurities may be irregularly doped.

Only the impurities without other contaminants may be implanted by the ion implantation method. Because the ion implantation method is performed at a relatively low temperature (e.g., not greater than 125° C.), the already deposited layers may not be affected by the ion implantation method. Because there is no limit in the solubility of a material subject to the implantation, a desired amount of impurities may be implanted. The depth of the implantation of the impurities may be adjusted. As such, even if a spacer exists under an etch prevention layer, the impurities may be implanted in the spacer.

For example, the impurities 130 may include at least one of carbon and fluorine. The impurities 130 may be implanted in units of atoms (i.e., as monomers) or in a cluster type in which the atoms form a cluster. Ion implantation energy may be selected such that a projection range (or depth of) the ion-implanted impurities 130 may be smaller than the thickness of the spacer 122. To adjust the depth of the ion implantation of the impurities 130, the ion implantation energy used for the ion implantation of the impurities 130 may be adjusted.

The dose of the impurities 130 that is ion implanted may be selected such that the concentration of the impurities 130 may be about 10²¹ atoms/cm³ to about 10²² atoms/cm³. For example, the impurities 130 may be vertically implanted in the semiconductor substrate 100, or at an angle to more uniformly implant the impurities 130 in the spacer 122 perpendicularly formed to the semiconductor substrate 100.

Prior to the ion implantation of the impurities 130, a mask (not shown) to expose the area in which ions are implanted may be selectively formed on the semiconductor substrate 100. The impurities 130 may be selectively ion-implanted only in a device or area corresponding to a critical pitch so that parasitic capacitance generated in the device or area may be reduced. If the semiconductor substrate 100 is divided into a cell area and a circuit area, the impurities 130 may be ion-implanted only in either the cell area or the circuit area. The impurities 130 may be ion-implanted only in any of the above areas using a mask that exposes only an NMOS area or PMOS area of the semiconductor substrate 100. The formation of a mask prior to the ion implantation is an example, and therefore not limited thereto.

An annealing process to activate the impurities 130 may be selectively performed. During the annealing process, the spacer 122 may undergo lattice damaged by the ion implantation of the impurities 130. The lattice damage may be recovered by self annealing in the ion implantation process. However, if the self annealing is not sufficient, the semiconductor substrate 100 may be annealed for the stabilization of the spacer 122 through mono-crystal recovery and the activation of impurity atoms.

Referring to FIGS. 1 and 2E, highly-doped source/drain regions 108a and 108b may be formed using the gate stack 110 and the spacer 124 as a mask (S70). To form the highly-doped source/drain regions 108a and 108b, an appropriate mask layer (not shown) may be formed by, for example, a photolithography method. For example, after a mask layer is formed to expose the active region 106 in which an NMOS transistor is to be formed, the highly-doped source/drain regions 108a and 108b may be formed in the active region 106 by implanting n-type impurities (e.g., arsenic (As)). In another example, after a mask layer is formed to expose the active region 106 in which a PMOS transistor is to be formed, the highly-doped source/drain regions 108a and 108b may be formed in the active region 106 by implanting p-type impurities (e.g., boron (B)). An annealing process may be performed. The annealing process may be, for example, a rapid temperature process (RTP) or a laser annealing (LSA) process.

A semiconductor device fabricated according to the above-described method is discussed below. FIG. 7 is a graph for explaining a degree of a decrease in the parasitic capacitance of a semiconductor device fabricated according to the method of FIG. 1. In example embodiments, the spacer 122 is formed of a nitride, and carbon is used as the impurities 130.

Referring to FIGS. 2E and 7, the diamond shaped points indicates a rate of measured parasitic capacitance that is directly measured decreasing. The square shaped points indicates a rate of effective parasitic capacitance decreasing, the effective parasitic capacitance contributing to AC delay by measuring the AC delay generated if an actual semiconductor device is driven.

As illustrated in FIG. 7, as the impurities 130 is implanted, a dielectric constant of the parasitic capacitance decreases. If the impurities 130 are ion implanted in the spacer 122 such that the concentration of the impurities 130 reaches about 10²¹ atoms/cm³, the dielectric constant of the spacer 122 decreases from about 7.5 to about 5. As the impurities 130 are further implanted, the dielectric constant of the spacer 122 may be reduced to about 3.

If the dielectric constant of the spacer 122 is about 5, the measured parasitic capacitance decreases by about 5% and the AC delay decreases by about 4%. That is, the effective parasitic capacitance contributing to the AC delay decreases by about 4%.

If the dielectric constant of the spacer 122 is decreased to about 3 as the impurities 130 are further implanted, the measured parasitic capacitance decreases by about 10% and the AC delay (i.e., the effective parasitic capacitance) decreases by about 9%.

In the operation of ion implanting the impurities 130 (S60), the impurities 130 may be implanted not only in the spacer 122 but also in the lightly-doped source/drain regions 104a and 104b. In this case, tension/compression stress may be applied to the lightly-doped source/drain regions 104a and 104b according to the size, concentration and substitution of the impurities 130, and a process environment (e.g., a process temperature). The tension/compression stress may be applied to a channel area located between the lightly-doped source/drain regions 104a and 104b. As such, the mobility of a carrier passing through the channel area may be adjusted.

For the NMOS transistor, if carbon atoms are ion implanted in the lightly-doped source/drain regions 104a and 104b, the carbon atom is substituted by a silicon atom having a larger atomic radius than that of the carbon atom so that a silicon lattice is contracted. Compression stress is applied to the lightly-doped source/drain regions 104a and 104b. As a reaction to the compression, the channel area receives tension stress so that the mobility of electrons passing through the channel area may be increased. In this case, the rate of the carbon atoms substituted by the silicon atoms may be not greater than 2%.

For the PMOS transistor, if a carbon cluster having a large atomic radius in the lightly-doped source/drain regions 104a and 104b, the carbon cluster is inserted between the silicon atom lattice so that tension stress may be applied to the lightly-doped source/drain regions 104a and 104b. In this case, as a reaction to the tension stress, compression stress is applied to the channel area so that the mobility of holes passing through the channel area may be increased.

As such, the mobility of the carrier may be adjusted by the ion implantation. The operational characteristic of a semiconductor device may increase.

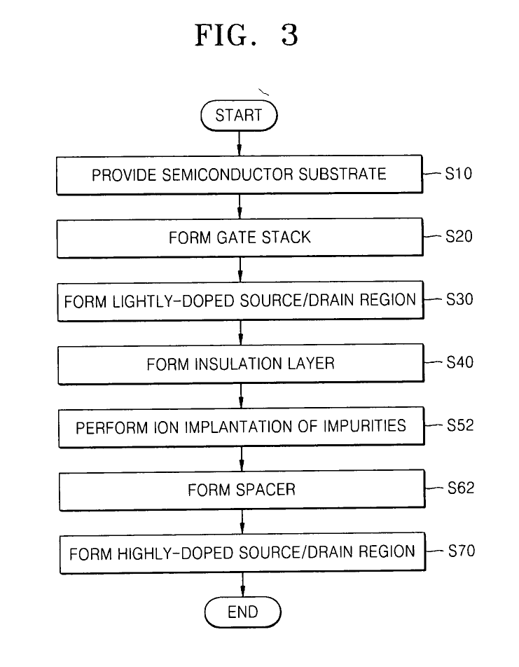

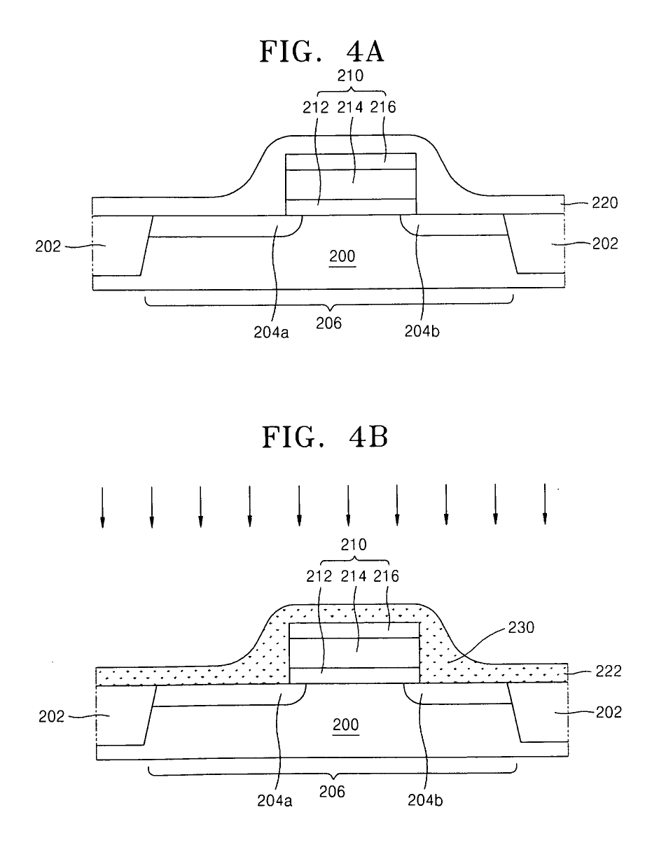

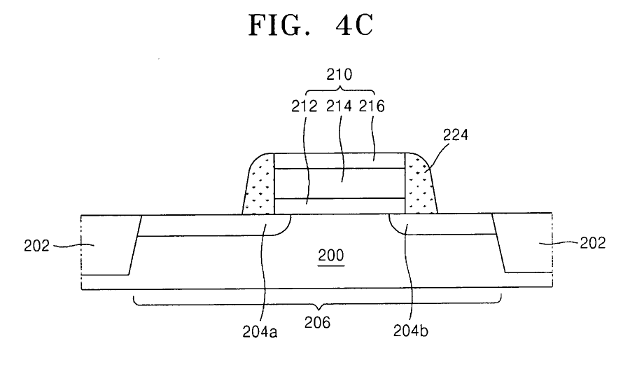

FIG. 3 is a flowchart for explaining a method of fabricating a semiconductor device according to example embodiments. FIGS. 4A-4C are cross-sectional views for showing the process sequence of a method of fabricating a semiconductor device according to example embodiments.

The method of example embodiments is different from the method of FIG. 1 in that the order of the operation S50 of FIG. 1 for forming a spacer and the operation S60 of FIG. 1 for performing ion implantation of the impurities is switched. Accordingly, the operations before the operation S50 and after the operation S60 will be briefly described in the following description.

Referring to FIGS. 3 and 4A, the cross-section of FIG. 4A is substantially the same as that of FIG. 2B. A semiconductor substrate 200 in which an active region 206 is defined by a device isolation layer 202 is provided (S10). A gate insulation layer 212, a gate electrode layer 214 and a capping layer 216 are sequentially formed on and above the semiconductor substrate 200. The gate insulation layer 212, a gate electrode layer 214 and a capping layer 216 are patterned, forming a gate stack 210 that is located in the active region 206 (S20). Lightly-doped source/drain regions 204a and 204b are formed at both sides of the gate stack 210 by performing ion implantation using the gate stack 210 as a mask (S30). An insulation layer 220 is formed on the semiconductor substrate 200 in which the gate stack 210 is formed (S40). As described above, the insulation layer 220 may include a nitride layer, an oxide layer, or a multi-layer structure of the nitride layer and the oxide layer which are sequentially deposited.

Referring to FIGS. 3 and 4B, impurities 230 may be ion implanted on the semiconductor substrate 200 in which the insulation layer 220 is formed in an upper portion thereof (S52). As described above, the impurities may include monomers, or clusters, of carbon, fluorine, or a combination thereof. The ion implantation energy may be selected such that the depth of implantation of the impurities 230 may not be greater than the thickness of the insulation layer 220 to prevent the impurities 230 from being implanted in the insulation layer 220. The dose of the impurities 230 may be selected such that the concentration of the impurities 230 may be about 10²¹ atoms/cm³ to about 10²² atoms/cm³.

As illustrated in FIG. 4B, an insulation layer 222 in which the impurities 230 are implanted is formed. The insulation layer 222 has a dielectric constant lower than that of the insulation layer 220 of FIG. 4A. For example, if the insulation layer 222 is formed of a nitride and the concentration of the impurities 230 is about 10²¹ atoms/cm³, the dielectric constant of the insulation layer 222 is decreased from about 7.5 to about 5.

As described above in relation to the semiconductor shown in FIG. 1, a mask layer (not shown) to block the ion implantation may be formed prior to the ion implantation of the impurities 230. The impurities 230 may be ion implanted only in an area that is designed with a critical pitch at which parasitic capacitance is of a concern.

Referring to FIGS. 3 and 4C, the insulation layer 222 in which the impurities 230 may be ion implanted is etched such that the upper surface of the gate stack 210 and most (or a substantial portion) of the active region 206 except for the gate stack 210 may be exposed. A spacer 224 may be formed by leaving the insulation layer 222 only at both side walls of the gate stack 210 (S62). As described above, an overall surface etching process such as etch back (e.g., reactive ion etching (RIE) that is anisotropic etching) may be used to form the spacer 224.

The insulation layer 222 in which the impurities 230 are implanted may not endure the etching process due to a surface damage generated during the ion implantation process. Thus, the insulation layer 222 may be densified (i.e., the density increased) through an annealing process prior to the etching of the insulation layer 222 to form the spacer 224. The above process is selective and may be omitted in example embodiments.

As described above with reference to the semiconductor device shown in FIG. 1, the impurities 230 are ion implanted in the active region 206 using the gate stack 210 and the spacer 24 as a mask, forming highly-doped source/drain regions 208a and 208b (S70). According to the method of fabricating a semiconductor device according to example embodiments, by ion implanting the impurities 230 prior to the forming of the insulation layer 220 into the spacer 224, the implantation of the impurities 230 in the highly-doped source/drain regions 208a and 208b may be prevented (or reduced).

As described above, different impurities may be selectively implanted in the NMOS region or the PMOS region to adjust channel stress. In some instances, it may not be necessary to implant the impurities in the highly-doped source/drain regions 208a and 208b. The implantation of impurities in the highly-doped source/drain regions 208a and 208b may be prevented without a separate mask layer, by using the insulation layer 220 as a mask for the highly-doped source/drain regions 208a and 208b.

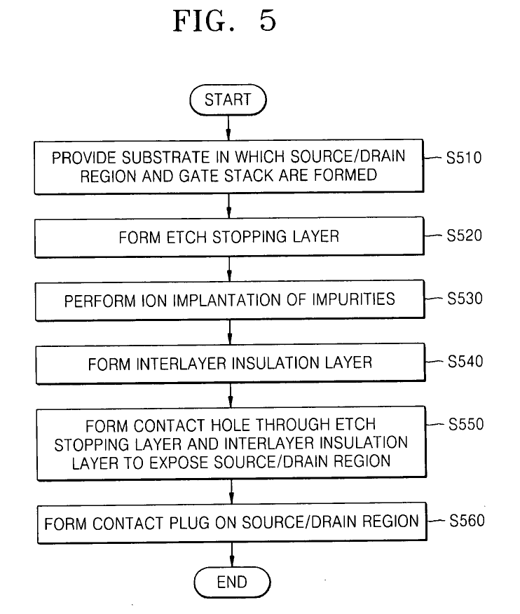

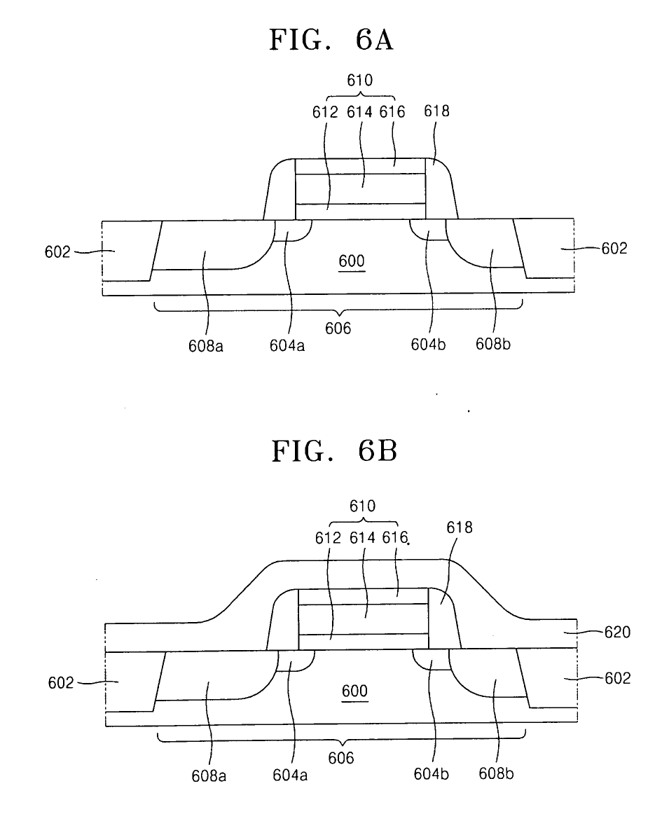

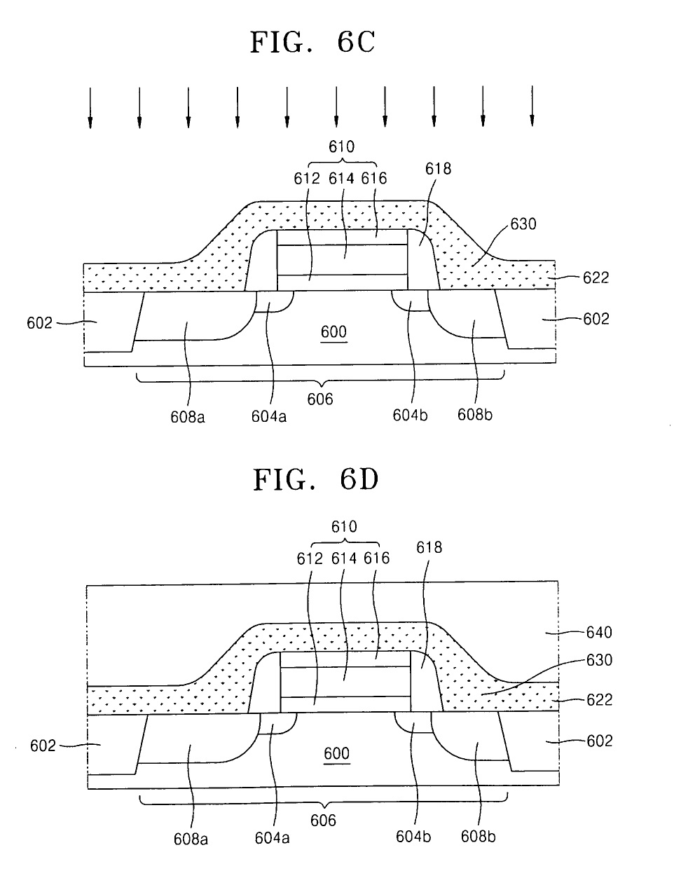

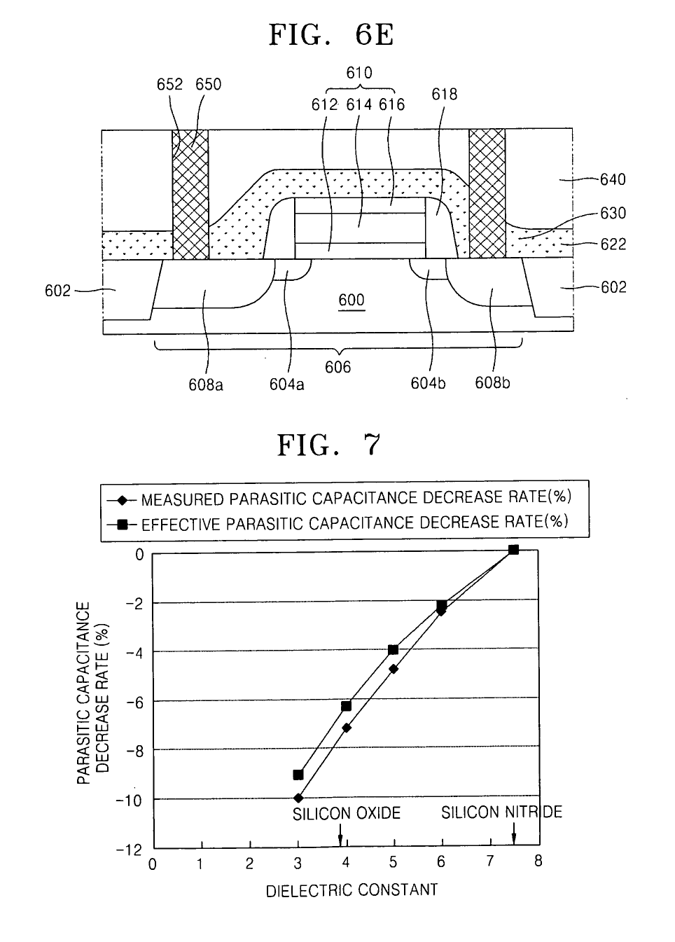

FIG. 5 is a flowchart for explaining a method of fabricating a semiconductor device according to example embodiments. FIGS. 6A-6E are cross-sectional views for showing the process sequence of a method of fabricating a semiconductor device according to example embodiments.

Referring to FIGS. 5 and 6A, a semiconductor substrate 600 in which an active region 606 is defined by a device isolation layer 602 (S510). The active region 606 of the semiconductor substrate 600 includes highly-doped source/drain regions 608a and 608b. The active region 606 may include lightly-doped source/drain regions 604a and 604b.

The semiconductor substrate 600 includes a gate stack 610 located in the active region 606 of the semiconductor substrate 600 located between the highly-doped source/drain regions 608a and 608b. The gate stack 610 may be formed by sequentially depositing a gate insulation layer 612, a gate electrode 614 and a capping layer 616, and pattering the deposited layers (as described above). The capping layer 616 may be omitted in some example embodiments.

A spacer 618 may be formed at both side walls of the gate stack 610. Impurities (e.g., carbon or fluorine) may be ion implanted in the spacer 618 according to the above-described embodiments of FIG. 1 and FIG. 3. However, example embodiments are not limited to the spacer including the impurities. It may not be necessary that the spacer is formed at both side walls of the gate stack 610.

To help understanding of example embodiments, the gate stack 610 is described to include not only the gate insulation layer 612, the gate electrode 614 and the capping layer 616 that are sequentially deposited, but also the spacer 618 formed at both side walls of the gate stack 610. Because these constituent elements are described in detail in the above descriptions of FIG. 1 and FIG. 3, detailed descriptions thereon will be omitted herein for the sake of brevity.

Although it is not illustrated in FIG. 6A, a metal silicide layer (not shown) may be formed on the highly-doped source/drain regions 608a and 608b, using silicide technology. The metal silicide layer may decrease contact resistance with respect to a contact plug to be formed in the subsequent process. The metal silicide layer may include a metal material (e.g., tungsten (W) or cobalt (Co)).

Referring to FIGS. 5 and 6B, an etch stopping layer 620 is formed on the semiconductor substrate 600 in which the gate stack 610 and the highly-doped source/drain regions 608a and 608b are formed (S520). The etch stopping layer 620 may include at least one of a nitride, an oxide and an oxy-nitride (e.g., a silicon nitride, a silicon oxide or a silicon oxy-nitride). The etch stopping layer 620 may be formed in a variety of methods such as CVD, LPCVD, PECVD, HDP-CVD, sputtering or ALD.

The etch stopping layer 620 (e.g., a silicon nitride layer) may receive tension/compression stress. Tension stress or compression stress may be applied to the silicon nitride layer according to the ratio of N—H bonding and Si—H bonding in the silicon nitride layer. If the N—H bonding is one to five times greater than the Si—H bonding, the tension stress may be applied. If the N—H bonding is five to twenty times greater than the Si—H bonding, the compression stress may be applied. The vertical mobility of a carrier may be adjusted.

Referring to FIGS. 5 and 6C, the impurities 630 may be ion implanted in the semiconductor substrate 600 in which the etch stopping layer 620 is formed (S530). An etch stopping layer 622 including the impurities 630 and having a reduced dielectric constant may be formed.

In example embodiments, the impurities 630 may include at least one of carbon and fluorine. The impurities 630 may be implanted in units of atoms (i.e., as monomers) or in a cluster type in which the atoms form a cluster. The dose of the ion-implanted impurities may be selected such that the concentration of the impurities 630 may be about 10²¹ atoms/cm³ to about 10²² atoms/cm³.

Ion implantation energy may be selected such that a projection range (or depth of) the ion-implanted impurities 630 may be smaller than the thickness of the etch stopping layer 622. If the impurities 630 are ion implanted in the etch stopping layer 622 at a depth greater than the thickness of the etch stopping layer 622, the impurities 630 are implanted even in the highly-doped source/drain regions 608a and 608b under the etch stopping layer 622 so that the operational characteristics of a semiconductor device may be unexpectedly changed.

If the spacer 618 is formed on the gate stack 610, the ion implantation energy may be selected such that the impurities 630 may be implanted in the spacer 618. The dielectric constant of both of the spacer 618 and the etch stopping layer 622 may be lowered by performing the ion implantation process of the impurities 630 simultaneously, which is economical.

In example embodiments, an ion implantation apparatus may be used to ion implant the impurities 630. For example, the PIII or the PII may be used. The impurities 630 may be vertically implanted in the semiconductor substrate 600, or at an angle to uniformly implant the impurities 630 in the etch stopping layer 622 located at the side wall of the gate stack 610 perpendicularly formed to the semiconductor substrate 600.

In example embodiments, prior to the ion implantation of the impurities 630, a mask (not shown) to expose an area in which the impurities 630 are ion implanted may be formed on the semiconductor substrate 600. In other words, parasitic capacitance generated in the area in which the impurities 630 are ion implanted may be reduced by selectively ion implanting the impurities 630 only in the area corresponding to a critical pitch. The formation of a mask prior to the ion implantation is an example, and therefore not limited thereto. An annealing process may be performed after the ion implantation of the impurities 630.

Referring to FIGS. 5 and 6D, an interlayer insulation layer 640 may be formed on the etch stopping layer 622 in which the impurities 630 are implanted (S540). The interlayer insulation layer 640 may be formed of the same material as, or a different material from, that of the etch stopping layer 620 located thereunder. The interlayer insulation layer 640 may include at least one of a nitride, an oxide and an oxy-nitride (e.g., a silicon nitride, a silicon oxide or a silicon oxy-nitride). The inter layer insulation layer 640 may be formed by a variety of methods such as CVD, LPCVD, PECVD, HDP-CVD, sputtering or ALD.

Referring to FIGS. 5 and 6E, the highly-doped source/drain regions 608a and 608b may be exposed by partially etching the etch stopping layer 620 and the interlayer insulation layer 640 (S550). A mask layer (not shown) patterned to expose the areas of contact plugs 650 that are to be formed on the highly-doped source/drain regions 608a and 608b may be formed on the interlayer insulation layer 640 by a photolithography process. The areas of the etch stopping layer 620 and the interlayer insulation layer 640 where the contact plugs 650 are to be formed may be removed by anisotropic etching (e.g., ion sputtering etching) and/or isotropic etching. Contact holes 652 to expose the highly-doped source/drain regions 608a and 608b may be formed. The contact plugs 650 contacting the highly-doped source/drain regions 608a and 608b may be formed by filling a conductive material in the contact holes 652 (S560).

The conductive material may include tungsten (W), aluminum (Al), titanium (Ti) or poly silicon. The contact plugs 650 may be formed in a variety of methods such as PVD, CVD, LPCVD, PECVD, HDP-CVD, sputtering or ALD. A planarization process may be performed to remove a metal material formed on the interlayer insulation layer 640.

Referring to the semiconductor device fabricated according to example embodiments, insulation members (i.e., the spacer 618 and the etch stopping layer 620) are formed between the gates electrode 614 and the contact 652 which are conductive members, constituting a sort of capacitor. As described above, as the impurities 630 are implanted, the dielectric constants of the spacer 618 and the etch stopping layer 622 are decreased so that parasitic capacitance may be reduced.

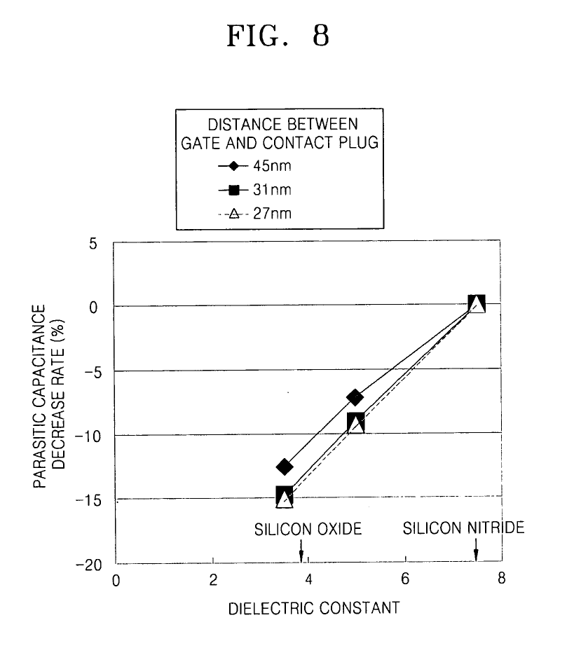

FIG. 8 is a graph for explaining a degree of a decrease in the parasitic capacitance of a semiconductor device fabricated according to the method of FIG. 5. The graph of FIG. 8 indicates a degree of a decrease in the parasitic capacitance according to the distance between the gate stack and the contact.

Referring to FIGS. 6E and 8, the etch stopping layer 620 is formed of a nitride. In example embodiments in which carbon is used as the impurities 630, if the impurities 630 are implanted such that concentration of the impurities 630 reaches about 10²¹ atoms/cm³, the dielectric constant is reduced from about 7.5 to about 5.

As illustrated in FIG. 8, if the interval between the gate stack 610 and the contact plugs 650 is 45-nm on the graph with diamond shaped points, the parasitic capacitance is reduced by about 7%. If the interval between the gates stack 610 and the contact plugs 650 is 31-nm and 27-nm, respectively, on the graphs with square shaped points and triangular points, the parasitic capacitance is reduced by about 9%.

If the impurities 640 are implanted by increasing the concentration of the impurities 630 such that the dielectric constant of the etch stopping layer 620 may be approximately similar to that of a silicon oxide, and if the interval between the gate stack 610 and the contact plugs 650 is 45-nm in the graph with diamond shaped points, the parasitic capacitance is reduced by about 13%. If the interval between the gates stack 610 and the contact plugs 650 is 31-nm and 27-nm, respectively, in graphs with square shaped points and triangular points, the parasitic capacitance is reduced by about 15%. It may be seen from FIG. 8 that the reduction rate of the parasitic capacitance increases as the interval between the gate stack 610 and the contact plugs 650 decreases.

As described above, according to example embodiments, as the parasitic capacitance decreases, the AC delay decreases. In the semiconductor device fabricated according to example embodiments, performance of the semiconductor device may increase by decreasing the AC delay.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A method of fabricating a semiconductor device, the method comprising:
forming a gate stack on a substrate;
forming an insulation layer on the substrate to cover the gate stack;
forming a spacer at on each side wall of the gate stack by etching the insulation layer; and
performing a first ion implantation to implant a plurality of first impurities in the spacer or the insulation layer.

2. The method of claim 1, wherein the first impurities are implanted in the spacer to reduce a dielectric constant of the spacer.

3. The method of claim 1, wherein the insulation layer includes a nitride.

4. The method of claim 1, wherein the first impurities include at least one selected from the group consisting of carbon, fluorine and combinations thereof.

5. The method of claim 1, wherein the first impurities are either monomers or clusters.

6. The method of claim 1, further comprising: prior to performing the first ion implantation, forming a mask layer to expose an ion implantation area on the substrate.

7. The method of claim 1, wherein, a dose of the first impurities is selected such that a concentration of the first impurities in the spacer or the insulation layer is between about 10²¹ atoms/cm³ to about 10²² atoms/cm³.

8. The method of claim 1, further comprising:
forming an etch stopping nitride layer on the substrate; and
performing a second ion implantation to implant a plurality of second impurities in the etch stopping nitride layer.

9. The method of claim 8, further comprising:
prior to forming the etch stopping nitride layer, forming a source/drain region in the substrate at both sides of the gate stack;
forming an interlayer insulation layer on the etch stopping nitride layer having the implanted second impurities;
forming a contact hole through the interlayer insulation layer and the etch stopping nitride layer to expose a portion of the source/drain region; and
forming a contact plug in the contact hole and on the exposed portion of the source/drain region.

10. The method of claim 1, wherein the first impurities are implanted in the insulation layer, prior to forming the spacer.

11. The method of claim 10, wherein performing the first ion implantation includes selecting an ion implantation energy such that a depth of the first impurities implanted in the insulation layer is smaller than a thickness of the insulation layer.

12. The method of claim 10, further comprising annealing the substrate to increase a density of the insulation layer, prior to etching the insulation layer.

13. A method of fabricating a semiconductor device, the method comprising:
forming a gate stack on a substrate;
forming a spacer at both side walls of the gate stack;
forming an etch stopping layer on the gate stack to cover the gate stack; and
performing a second ion implantation to implant a plurality of second.

14. The method of claim 13, further comprising:
prior to forming the etch stopping layer, forming a source/drain region in the substrate at both sides of the gate stack by ion implantation;
forming an interlayer insulation layer on the etch stopping layer having the implanted second impurities;
forming a contact hole through the interlayer insulation layer and the etch stopping layer to expose a portion of the source/drain region; and
forming a contact plug in the contact hole and on the exposed portion of the source/drain region.

15. The method of claim 13, further comprising:
forming an insulation layer on the substrate to cover the gate stack, prior to forming the spacer; and
performing a first ion implantation to implant a plurality of first impurities in the spacer to reduce a dielectric constant of the spacer, prior to forming the etch stopping layer,
wherein the spacer is formed by etching the insulation layer.

16. The method of claim 13, wherein the etch stopping layer includes a nitride, and the second impurities include at least one selected from the group consisting of carbon, fluorine and combinations thereof.

17. The method of claim 13, wherein the second impurities are either monomers or clusters.

18. The method of claim 13, further comprising: prior to performing the second ion implantation, forming a mask layer to expose an ion implantation area on the substrate.

19. The method of claim 13, wherein, a dose of the second impurities is selected such that a concentration of the second impurities in the etch stopping layer is between about 10²¹ atoms/cm³ to about 10²² atoms/cm³.

20. The method of claim 13, further comprising:
forming an insulation layer on the substrate to cover the gate stack; and
performing a first ion implantation to implant a plurality of first impurities in the insulation layer, prior to forming the spacer, wherein the spacer is formed by etching the insulation layer having the implanted first impurities.
